(19) United States
(12) Patent Application Publication
(10) Pub. No.: US 2025/0138055 A1
(43) Pub. Date: May 1, 2025

(54) CURRENT MEASUREMENT MODULE AND CURRENT MEASUREMENT DEVICE

(71) Applicant: Asahi Kasei Microdevices Corporation, Tokyo (JP)

(72) Inventor: Takehiro MARUYAMA, Tokyo (JP)

(21) Appl. No.: 18/923,695

(22) Filed: Oct. 23, 2024

(30) Foreign Application Priority Data
Oct. 25, 2023 (JP) 2023-183511
Oct. 22, 2024 (JP) 2024-185791

(51) Int. Cl. G01R 15/20

(52) U.S. Cl. CPC G01R 15/202

(57) ABSTRACT

There is provided a current measurement module including: a conductor which has two main body units arranged side by side in a first direction, and two current paths arranged side by side across a through hole in a second direction perpendicular to the first direction, and connecting the two main body units; and two magnetic detection elements which include magnetic sensing surfaces for detecting a component in a third direction perpendicular to the first direction and the second direction, in magnetic fields that are generated by currents flowing through the two current paths, and which are arranged side by side in the second direction, in which when viewed from the third direction, the two magnetic detection elements are arranged inside the through hole, and in the second direction, a center position between the two magnetic detection elements is close to either one of the two current paths.

### BACKGROUND

### 1. Technical Field

The present invention relates to a current measurement module and a current measurement device.

### 2. Related Art

Patent Document 1 discloses a “sensing system for contactless sensing of currents flowing through a conductor”.

### PRIOR ART DOCUMENTS

### Patent Document

Patent Document 1: Specification of U.S. Patent Application Publication No. 2023/0204632

### BRIEF DESCRIPTION OF THE DRAWINGS

FIG. 1 is a perspective view showing an example of a schematic configuration of a current measurement module 100 in a first embodiment.

FIG. 2 is a top plan view showing an example of the schematic configuration of the current measurement module 100 in the first embodiment.

FIG. 3 is a side cross-sectional view showing an example of the schematic configuration of the current measurement module 100 in the first embodiment.

FIG. 4 is a graph showing a relationship between a position (mm) of a magnetic detection element 21 in an x direction and a magnetic flux density (mT).

FIG. 5 is a graph showing a relationship between a center distance (mm) between two magnetic detection elements 21, 22 in the x direction, and the magnetic flux density (mT) that is detected.

FIG. 6 is a graph showing a relationship between a center distance (mm) between the two magnetic detection elements 21, 22 in the x direction, and the magnetic flux density (mT) that is detected.

FIG. 7 is a top plan view showing another example of the schematic configuration of the current measurement module 100 in the first embodiment.

FIG. 8 is a graph showing a relationship between widths of a conductor 10 and two current paths 13, 14 in the x direction, and a fluctuation rate (%) of the magnetic flux density that is detected.

FIG. 9 is a graph showing a relationship between the widths of the conductor 10 and the two current paths 13, 14 in the x direction, and the fluctuation rate (%) of the magnetic flux density that is detected.

FIG. 10 is a graph showing a relationship between the widths of the conductor 10 and the two current paths 13, 14 in the x direction, and the fluctuation rate (%) of the magnetic flux density that is detected.

FIG. 11 is a graph showing a relationship between the widths (mm) of the two current paths 13, 14 and the conductor 10 in the x direction, and the fluctuation rate (%) of the magnetic flux density from a time of 100 Hz.

FIG. 12 is a graph showing a relationship between the widths (mm) of the two current paths 13, 14 and the conductor 10 in the x direction, and the fluctuation rate (%) of the magnetic flux density from the time of 100 Hz.

FIG. 13 is a graph showing a relationship between the widths (mm) of the two current paths 13, 14 and the conductor 10 in the x direction, and the fluctuation rate (%) of the magnetic flux density from the time of 100 Hz.

FIG. 14 is a graph showing a relationship between the widths (mm) of the two current paths 13, 14 and the conductor 10 in the x direction, and the fluctuation rate (%) of the magnetic flux density from the time of 100 Hz.

FIG. 15 is a graph showing a relationship between a z coordinate of the one magnetic detection element 21 (or the magnetic detection element 22), and the magnetic flux density (mT) that is detected by the magnetic detection element 21.

FIG. 16 shows a first example of a method for fixing a magnetic detection unit 20 to the conductor 10.

FIG. 17 shows a second example of the method for fixing the magnetic detection unit 20 to the conductor 10.

FIG. 18 shows a third example of the method for fixing the magnetic detection unit 20 to the conductor 10.

FIG. 19 is a top plan view showing an example of a schematic configuration of a current measurement device 200 in a second embodiment.

FIG. 20 is a top plan view showing an example of a schematic configuration of a current measurement device 300 in a third embodiment.

FIG. 21 is a top plan view showing an example of a schematic configuration of a current measurement device 400 in a comparative example.

FIG. 22 is a graph showing a frequency characteristic of the current measurement device 200 in the second embodiment.

FIG. 23 is a graph showing the frequency characteristic of the current measurement device 200 in the second embodiment.

FIG. 24 is a graph showing the frequency characteristic of the current measurement device 200 in the second embodiment.

FIG. 25 is a graph showing a frequency characteristic of the current measurement device 400 in the comparative example.

FIG. 26 is a graph showing the frequency characteristic of the current measurement device 400 in the comparative example.

FIG. 27 is a graph showing the frequency characteristic of the current measurement device 400 in the comparative example.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

### (Configuration of First Embodiment)

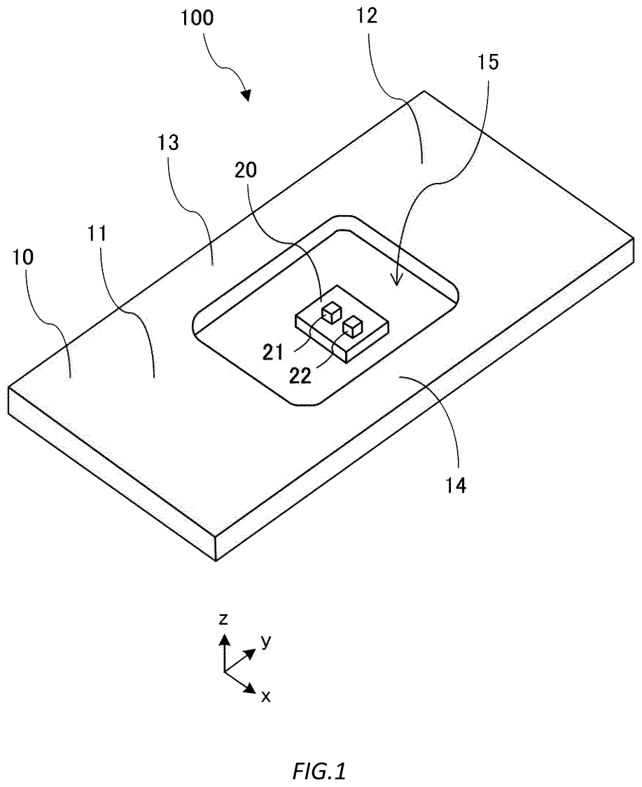

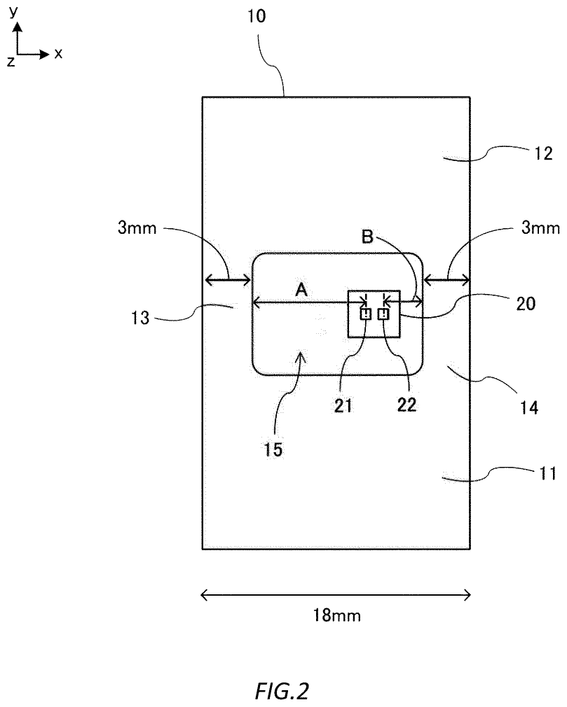

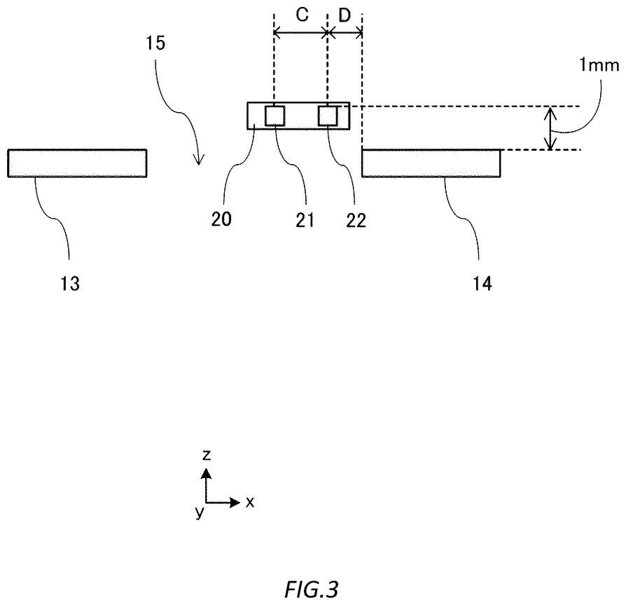

FIG. 1 is a perspective view showing an example of a schematic configuration of a current measurement module 100 in a first embodiment. FIG. 2 is a top plan view showing an example of the schematic configuration of the current measurement module 100 in the first embodiment. FIG. 3 is a side cross-sectional view showing an example of the schematic configuration of the current measurement module 100 in the first embodiment. In each drawing, an xyz coordinate system is shown. In the claims, a first direction is a y direction, a second direction is an x direction, and a third direction is a z direction. As shown in FIG. 1 to FIG. 3, the current measurement module 100 has a conductor 10 and a magnetic detection unit 20. The conductor 10 has two main body units 11, 12 and two current paths 13, 14, and has a through hole 15 formed by the two main body units 11, 12 and the two current paths 13, 14. It should be noted that the conductor 10 is also referred to as a bus bar. The magnetic detection unit 20 has two magnetic detection elements 21, 22.

As shown in FIG. 1 to FIG. 3, the two main body units 11, 12 are arranged side by side in the y direction. The two current paths 13, 14 are arranged between the two main body units 11, 12 and extend parallel to each other, and connect the two main body units 11, 12. The through hole 15 is arranged between the two current paths 13, 14. A current to be measured flows through each of the two current paths 13, 14 in the same direction. In the present embodiment, the two current paths 13, 14 are conductors having a rectangular transverse cross-sectional shape and extending linearly. It should be noted that the transverse cross-sectional shape of the two current paths 13, 14 may be any shape such as a circle or an ellipse.

As shown in FIG. 2, the two current paths 13, 14 have the same width in the x direction. The widths of the two current paths 13, 14 in the x direction are, for example, 3 mm. A width of the conductor 10 in the x direction is, for example, 18 mm. That is, a width of the through hole in the x direction is, for example, 12 mm. As the two current paths 13, 14 become thicker, an influence of the skin effect becomes great, and thus it is desirable for the widths of the two current paths 13, 14 in the x direction to be 4 mm or less. In addition, it is desirable for a thickness (a width in the z direction) of the conductor 10 to be 4 mm or less.

As shown in FIG. 2, the two magnetic detection elements 21, 22 are arranged side by side in the x direction. The two magnetic detection elements 21, 22 are arranged at a position close to either one of the two current paths 13, 14 in the x direction. In the example shown in FIG. 2, the two magnetic detection elements 21, 22 are arranged at a position close to the current path 14 and far from the current path 13. That is, in FIG. 2, A>B is satisfied. By setting such an arrangement, an intensity of a magnetic field that is detected from the one current path 14 which is set to be close becomes greater, and it is possible to enhance an S/N ratio of a signal that is detected. It should be noted that the two magnetic detection elements 21, 22 may be arranged at a position close to the current path 13 and far from the current path 14.

Each of the two magnetic detection elements 21, 22 detects the intensity of the magnetic field that is generated on each magnetic sensing surface by each of the currents to be measured flowing in the y direction through the two current paths 13, 14, and outputs a detection signal in accordance with a difference between the detection intensities detected respectively by the two magnetic detection elements 21, 22. That is, in the present embodiment, the detection signal that is output by the combination of the two magnetic detection elements 21, 22 is a differential output. The two magnetic detection elements 21, 22 are respectively arranged such that the magnetic field generated by each of the currents to be measured flowing in the same direction through the two current paths 13, 14 passes through the magnetic sensing surface. The two magnetic detection elements 21, 22 are arranged between the two current paths 13, 14 such that orientations of the magnetic sensing surfaces coincide with each other. In the present embodiment, the orientation of the magnetic sensing surface, that is, a normal direction of the surface, is the z direction.

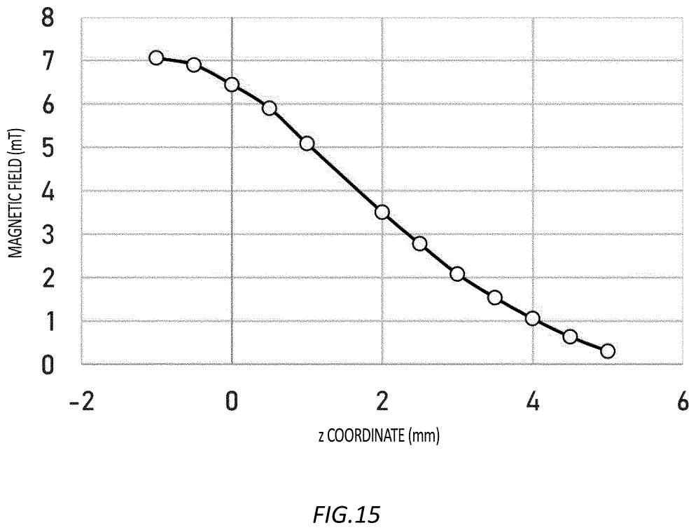

As shown in FIG. 2, when viewed from the z direction, the two magnetic detection elements 21, 22 are arranged in the through hole 15. As shown in FIG. 3, the magnetic detection unit 20 is arranged such that the positions of the magnetic sensing surfaces of the two magnetic detection elements 21, 22 in the z direction are 1 mm above an upper surface of the conductor 10. The magnetic detection unit 20 is fixed to the conductor 10 by an insulation member or the like (not shown). The method for fixing to the conductor 10 will be described in the description parts in FIG. 15 to FIG. 17.

As the two magnetic detection elements 21, 22, a magnetoelectric conversion element can be used, and as the magnetoelectric conversion elements, for example, a Hall element that is able to obtain the detection signal proportional to a magnitude of a magnetic flux density, can be used. It should be noted that as the magnetoelectric conversion element, in addition to the Hall element, a magnetoresistance element, a magnetic impedance element, or the like may be used. Further, as the two magnetic detection elements 21, 22, any device that generates a unique detection signal for the magnetic flux density that is applied, such as a magnetic sensor IC in which these magnetoelectric conversion elements are combined with an IC processing circuit, can be used. The two magnetic detection elements 21, 22 may be different from each other in shape or size.

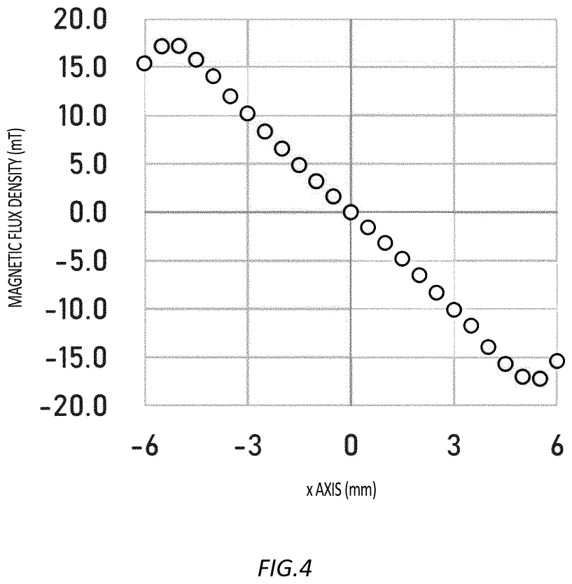

FIG. 4 is a graph showing a relationship between a position (mm) of a magnetic detection element 21 in an x direction and a magnetic flux density (mT) in the z direction. The graph in FIG. 4 shows the fluctuation in magnetic flux density that is detected when the one magnetic detection element 21 (or the magnetic detection element 22) is moved in the x direction in the through hole 15. In FIG. 4, the horizontal axis represents the position (mm) of the center of the magnetic detection element 21 in the x direction, and the vertical axis represents the magnetic flux density (mT) that is detected by the magnetic detection element 21. In FIG. 4, a region in which a value on the horizontal axis is positive, indicates that the magnetic detection element 21 is close to the current path 14, and a region in which a value on the horizontal axis is negative, indicates that the magnetic detection element 21 is close to the current path 13. In FIG. 4, a point of 0 mm on the horizontal axis indicates that the center of the magnetic detection element 21 in the x direction coincides with the center of the through hole 15 in the x direction.

As shown in FIG. 4, as the magnetic detection element 21 is placed to be close to the current path 13, the magnetic field that is generated by the current flowing through the current path 13 becomes strong, and thus the magnetic flux density that is detected, becomes great. In addition, as the magnetic detection element 21 is placed to be close to the current path 14, the magnetic field in an opposite direction that is generated by the current flowing through the current path 14 becomes strong, and thus the magnetic flux density that is detected, becomes small. Further, when the magnetic detection element 21 is arranged in the center of the current paths 13, 14, the magnetic field that is generated by the current flowing through the current path 13 and the magnetic field that is generated by the current flowing through the current path 14 cancel out each other, and the magnetic flux density that is detected becomes zero. It should be noted that when the magnetic detection element 21 is placed to be too close to the current path 13, a z direction component of the magnetic field from the current path 13 becomes small, and thus the magnetic flux density that is detected becomes small.

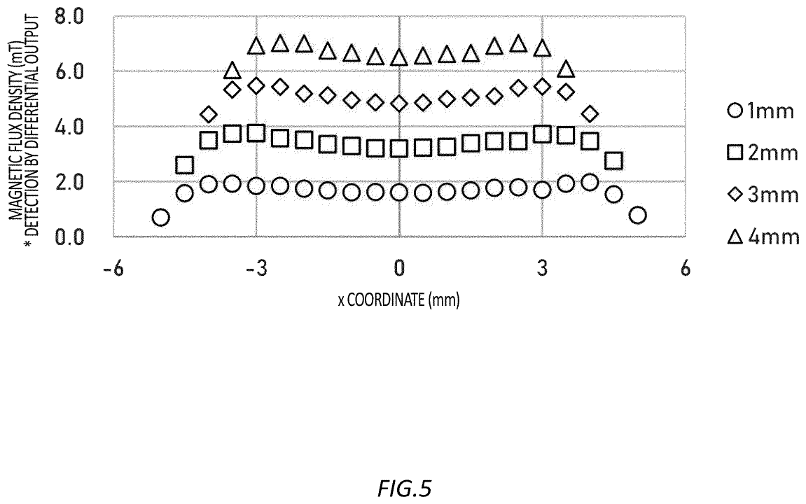

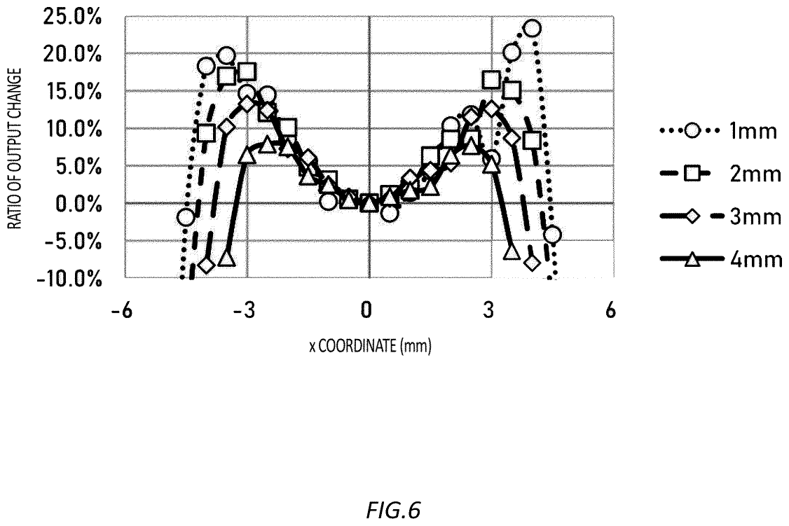

FIG. 5 and FIG. 6 are graphs showing the relationships between the center coordinate (mm) that is the coordinate of the center of the two magnetic detection elements 21, 22 in the x direction, and the magnetic flux density (mT) that is detected, for a center distance (mm) between the two magnetic detection elements 21, 22 in the x direction. The horizontal axis of FIG. 5 represents the center coordinate (mm) that is the coordinate of the center of the two magnetic detection elements 21, 22 in the x direction, and the center of the through hole 15 is set as the reference (x=0). The vertical axis of FIG. 5 represents the magnetic flux densities (mT) that are detected by the two magnetic detection elements 21, 22 by the differential output. The horizontal axis of FIG. 6 represents the center coordinate (mm) of the two magnetic detection elements 21, 22 in the x direction, and the center of the through hole 15 is set as the reference (x=0). The vertical axis of FIG. 6 represents a ratio (%) of an output change in the magnetic flux densities that are detected by the two magnetic detection elements 21, 22, in comparison with a case where the center coordinate of the two magnetic detection elements 21, 22 in the x direction is zero.

In FIG. 5 and FIG. 6, the point indicated by the circle indicates a case where the center distance between the two magnetic detection elements 21, 22 in the x direction is 1 mm; the point indicated by the square indicates a case where the center distance between the two magnetic detection elements 21, 22 in the x coordinate is 2 mm; the point indicated by the diamond indicates a case where the center distance between the two magnetic detection elements 21, 22 in the x coordinate is 3 mm; and the point indicated by the triangle indicates a case where the center distance between the two magnetic detection elements 21, 22 in the x coordinate is 4 mm. Here, the center distance between the two magnetic detection elements 21, 22 in the x direction is a distance between the center of the magnetic detection element 21 and the center of the magnetic detection element 22 in the x direction, and is indicated by “C” in FIG. 3.

As shown in FIG. 5, when the center distance is 4 mm, the magnetic flux density of approximately 6 mT or more is detected; however, when the center distance is 1 mm, only the magnetic flux density of approximately 2 mT or less is detected. That is, as the center distance between the two magnetic detection elements 21, 22 in the x direction becomes great, the value of the magnetic flux density that is detected by the differential output, becomes great. In addition, as shown in FIG. 6, as the x coordinates of the two magnetic detection elements 21, 22 are deviated from the center, the change rate in the output ratio becomes great. A case where the magnetic flux density that is detected is great, is desirable from the standpoint of the S/N ratio. Accordingly, a case where the center distance between the two magnetic detection elements 21, 22 in the x direction is great, is favorable, for example, 2 mm or more is favorable. In other words, it is preferable that the center distance between the two magnetic detection elements 21, 22 in the x direction is, for example, 10% or more, 15% or more, or 25% or more of the width of the through hole 15 in the x direction.

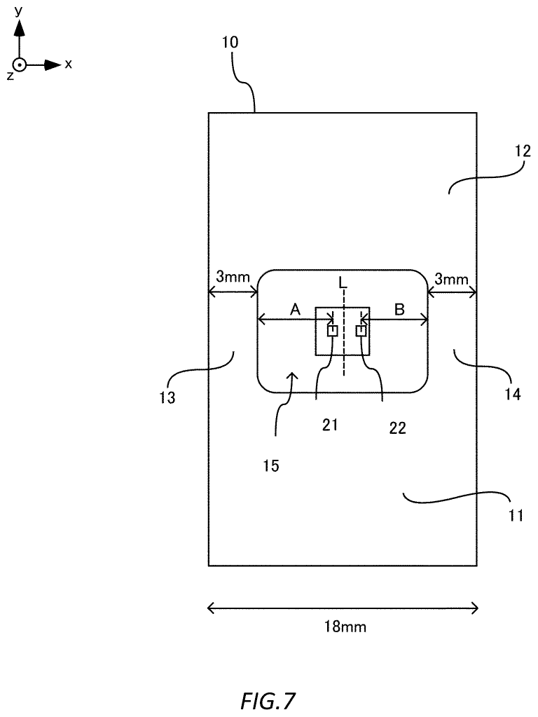

FIG. 7 is a top plan view showing another example of the schematic configuration of the current measurement module 100 in the first embodiment. In order to ensure the center distance between the two magnetic detection elements 21, 22 in the x direction and enhance the S/N ratio, for example, as shown in FIG. 7, the two magnetic detection elements 21, 22 may be arranged to face each other with respect to the center of the through hole 15. That is, the two magnetic detection elements 21, 22 may be arranged such that the two magnetic detection elements 21, 22 are respectively positioned on opposite sides of a center line L of the through hole 15 in the x direction. In addition, the two magnetic detection elements 21, 22 may be arranged to face each other across a region in which the magnetic fields that are generated by the currents flowing through the two current paths cancel out each other when the current flows through the conductor, and the magnetic flux density in the z direction that is detected becomes zero.

In addition, the arrangement may be made such that the center distance between the two magnetic detection elements 21, 22 in the x direction is greater than a distance between a center position of a magnetic detection element (the magnetic detection element 22 in FIG. 3), among the two magnetic detection elements 21, 22, in the x direction on a side of the first current path which is close to the center position between the two magnetic detection elements, and an end portion of the first current path (the current path 14 in FIG. 3) which is close to the center position between the two magnetic detection elements. That is, in FIG. 3, C>D may be satisfied.

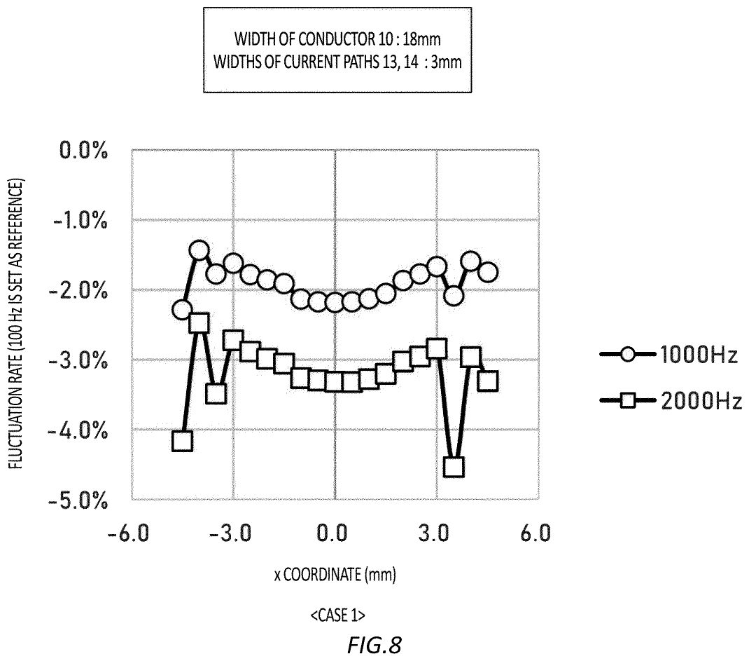

FIG. 8 to FIG. 10 are graphs showing the relationships between the center coordinate (mm) that is the coordinate of the center of the two magnetic detection elements 21, 22 in the x direction, and the fluctuation rate (%) of the magnetic flux density (mT) that is detected, for each of the widths of the conductor 10 and the two current paths 13, 14 in x direction. In FIG. 8 to FIG. 10, the horizontal axis represents the center position of the two magnetic detection elements 21, 22 in the x direction (that is, the center position of the magnetic detection element 21 and the magnetic detection element 22 in the x direction) (mm), and the center of the through hole 15 is set as the reference (x=0). In FIG. 8 to FIG. 10, the vertical axis represents the fluctuation rate (%) of the magnetic flux densities that are detected by the two magnetic detection elements 21, 22 in a case where 100 Hz is set as the reference. in FIG. 8 to FIG. 10, the white circle indicates the fluctuation rate of the magnetic flux density at a time of 1000 Hz, and the square indicates the fluctuation rate of the magnetic flux density at a time of 2000 Hz. It should be noted that in FIG. 8, there are regions in which the fluctuation rate exceeds 0%, which are not shown in the graph.

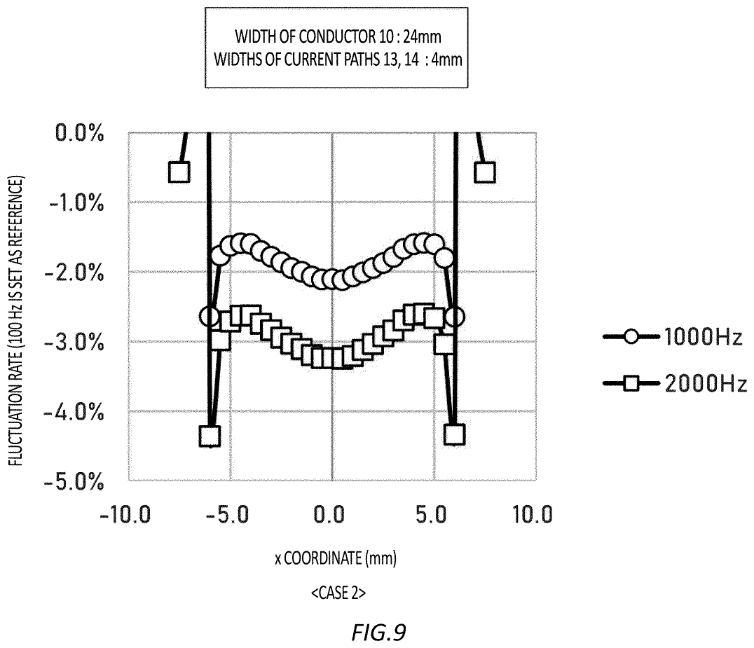

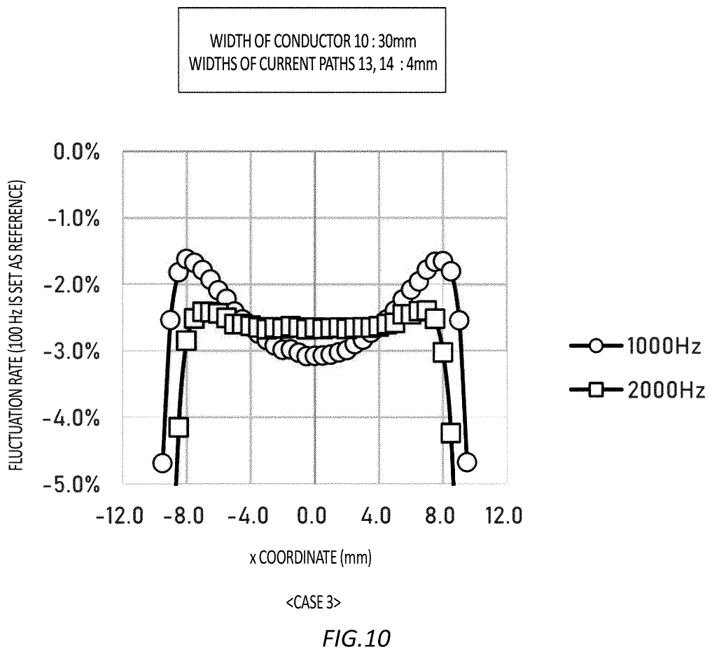

FIG. 8 shows a case 1 where the width of the conductor 10 in the x direction is 18 mm and the widths of the two current paths 13, 14 in the x direction are 3 mm; FIG. 9 shows a case 2 where the width of the conductor 10 in the x direction is 24 mm and the widths of the two current paths 13, 14 in the x direction are 4 mm; and FIG. 10 shows a case 3 where the width of the conductor 10 in the x direction is 30 mm and the widths of the two current paths 13, 14 in the x direction are 4 mm. It should be noted that in FIG. 8 to FIG. 10, the center distance between the two magnetic detection elements 21, 22 in the x direction is 3 mm; and the distance from the upper surface of the conductor 10, to the positions of the magnetic sensing surfaces of the two magnetic detection elements 21, 22 in the z direction, is 1 mm.

Here, for the fact that there are many regions in which the fluctuation rate of the magnetic flux density at the time of 2000 Hz is within-3%, it can be said that the fluctuation of a detection value due to a frequency is small, which is desirable from the viewpoint of a frequency characteristic. Among the case 1 to the case 3, the case 3 shown in FIG. 10 has the greatest number of regions in which the fluctuation rate of the magnetic flux density at the time of 2000 Hz is within-3%. Accordingly, among the case 1 to the case 3, the case 3 in which the width of the conductor 10 in the x direction is 30 mm and the widths of the two current paths 13, 14 in the x direction are 4 mm, is the most desirable.

In FIG. 8, for both of the two magnetic detection elements 21, 22, the coordinates which are 1 mm or more away from inner end portions of the two current paths 13, 14, are within a region of +3 mm on the horizontal axis. In FIG. 9, for both of the two magnetic detection elements 21, 22, the coordinates which are 1 mm or more away from the inner end portions of the two current paths 13, 14, are within a region of +5 mm on the horizontal axis. In FIG. 10, for both of the two magnetic detection elements 21, 22, the coordinates which are 1 mm or more away from the inner end portions of the two current paths 13, 14, are within a region of +8 mm on the horizontal axis.

Here, in a region outside+3 mm on the horizontal axis in FIG. 8, a region outside+5 mm on the horizontal axis in FIG. 9, and a region outside+8 mm on the horizontal axis in FIG. 10, the magnetic flux density fluctuates greatly. This is because when the two magnetic detection elements 21, 22 are placed to be too close to either of the two current paths 13, 14, they become susceptible to the skin effect, and the fluctuation rate by the frequency becomes great. Accordingly, from the viewpoint of the frequency characteristic, it is desirable to arrange both of the two magnetic detection elements 21, 22 to be 1 mm or more away from the inner end portions of the two current paths 13, 14 in the x direction.

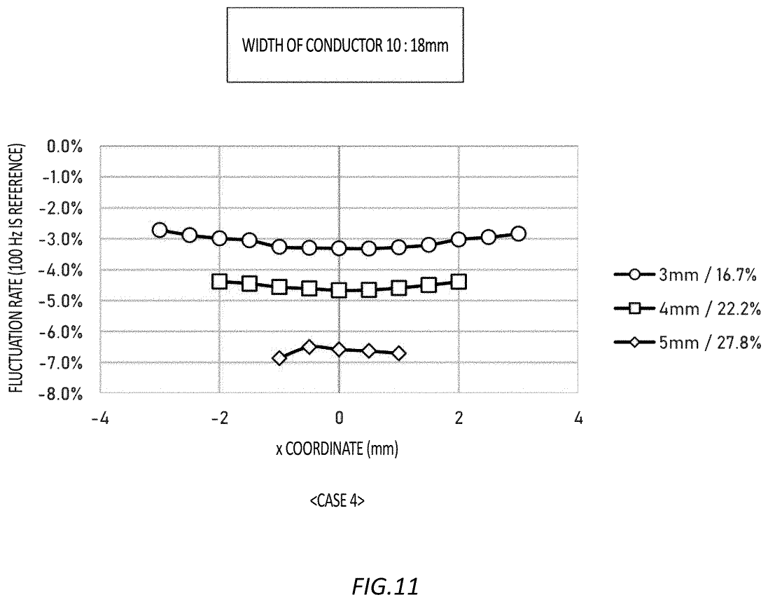

FIG. 11 to FIG. 14 are graphs showing a relationship between the widths (mm) of the two current paths 13, 14 and the conductor 10 in the x direction, and the fluctuation rate (%) of the magnetic flux density from a time of 100 Hz. In FIG. 11 to FIG. 14, the horizontal axis represents the center position of the two magnetic detection elements 21, 22 in the x direction (that is, the center position of the magnetic detection element 21 and the magnetic detection element 22 in the x direction) (mm), and the center of the through hole 15 is set as the reference (x=0). In FIG. 11 to FIG. 14, the vertical axis represents the fluctuation rate (%) of the magnetic flux densities that are detected by the two magnetic detection elements 21, 22 in a case where 100 Hz is set as the reference. In FIG. 11 to FIG. 14, the white circle indicates a case where the widths of the two current paths 13, 14 in the x direction are 3 mm; the square indicates a case where the widths of the two current paths 13, 14 in the x direction are 4 mm; and the diamond indicates a case where the widths of the two current paths 13, 14 in the x direction are 5 mm. In the right side of FIG. 11 to FIG. 14, the values obtained by dividing the widths of the two current paths 13, 14 in the x direction by the width of the conductor 10 in the x direction are shown.

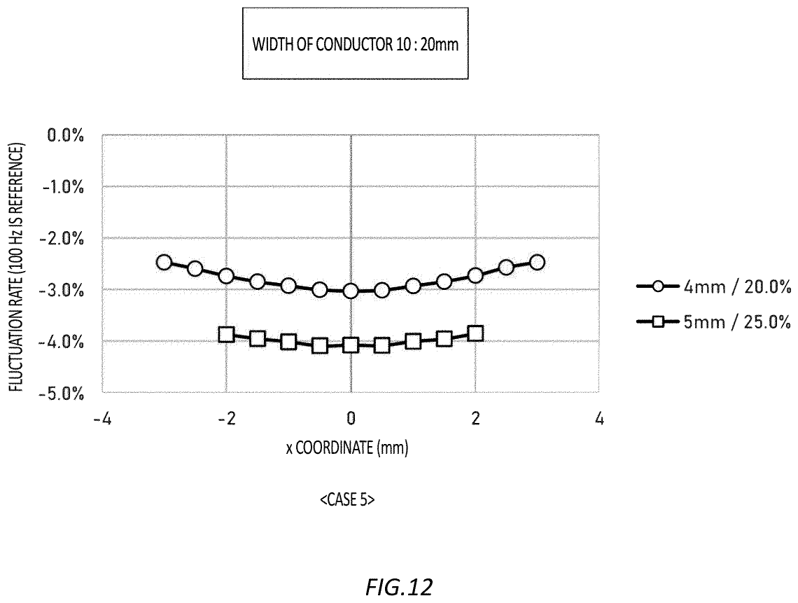

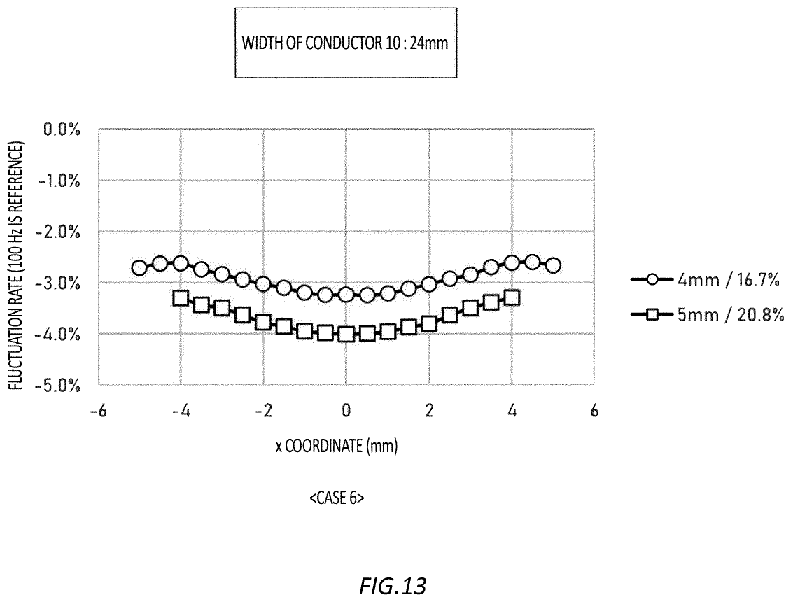

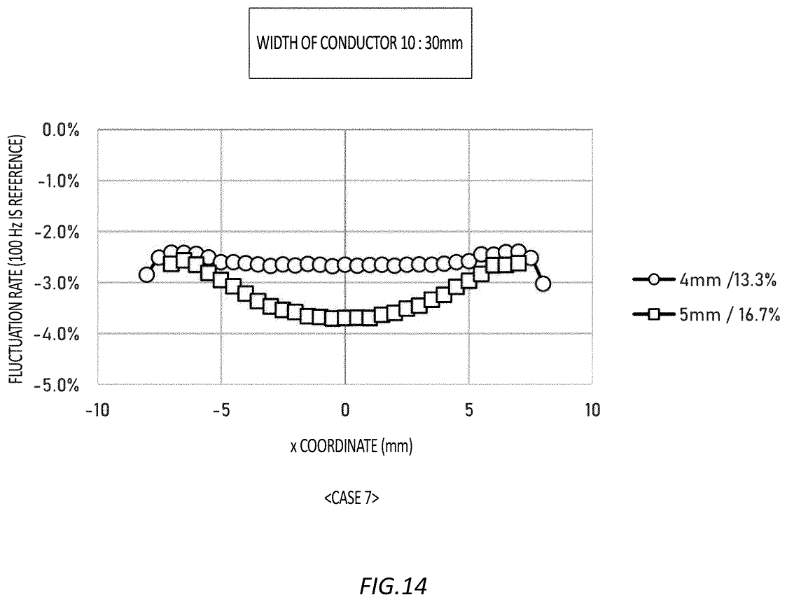

FIG. 11 shows a case 4 where the width of the conductor 10 in the x direction is 18 mm; FIG. 12 shows a case 5 where the width of the conductor 10 in the x direction is 20 mm; FIG. 13 shows a case 6 where the width of the conductor 10 in the x direction is 24 mm; and FIG. 14 shows a case 7 where the width of the conductor 10 in the x direction is 30 mm. It should be noted that In FIG. 11 to FIG. 14, the frequency of the current flowing through the conductor 10 is 2000 Hz; the center distance between the two magnetic detection elements 21, 22 in the x direction is 3 mm; and the distance from the upper surface of the conductor 10 in the z direction, to the positions of the magnetic sensing surfaces of the two magnetic detection elements 21, 22 in the z direction, is 1 mm. In FIG. 11 to FIG. 14, the more the regions in which the fluctuation rate of the magnetic flux density at the time of 2000 Hz is within-3%, the more desirable from the viewpoint of a frequency characteristic.

As shown in FIG. 11, in the case 4 where the width of the conductor 10 in the x direction is 18 mm, when the widths of the two current paths 13, 14 in the x direction are 3 mm, the fluctuation rate of the magnetic flux density is around −3%, which is a desirable value; however, when the widths of the two current paths 13, 14 in the x direction are 4 mm or 5 mm, the fluctuation rate exceeds-4%, which is not desirable. As shown in FIG. 12, in the case 5 where the width of the conductor 10 in the x direction is 20 mm, when the widths of the two current paths 13, 14 in the x direction are 4 mm, the fluctuation rate is approximately within-3%, which is a desirable value; however, when the widths of the two current paths 13, 14 in the x direction are 5 mm, the fluctuation rate is around −4%, which is not desirable.

As shown in FIG. 13, in the case 6 where the width of the conductor 10 in the x direction is 24 mm, when the widths of the two current paths 13, 14 in the x direction are 4 mm, the fluctuation rate is around −3%, which is a desirable value; however, when the widths of the two current paths 13, 14 in the x direction are 5 mm, the fluctuation rate exceeds-3%, which is not desirable. As shown in FIG. 14, in the case 7 where the width of the conductor 10 in the x direction is 30 mm, when the widths of the two current paths 13, 14 in the x direction are 4 mm, the fluctuation rate is within-3%, which is a desirable value; and when the widths of the two current paths 13, 14 in the x direction are 5 mm, the fluctuation rate is a value around −3%, which is also a desirable value.

From the above description, for the combination of the widths of the conductor 10 and the two current paths 13, 14, the desirable combinations are 18 mm and 3 mm in the case 4; 20 mm and 4 mm in the case 5; 24 mm and 4 mm in the case 6; and 30 mm and 4 mm, and 30 mm and 5 mm in the case 7. Accordingly, it can be seen that when the value obtained by dividing the widths of the two current paths 13, 14 in the x direction by the width of the conductor 10 in the x direction is 20% or less, the fluctuation rate becomes the desirable value.

When the current paths 13, 14 are thick, the influence of the skin effect becomes great, and thus the frequency characteristic deteriorates. Therefore, from the viewpoint of the frequency characteristic, it is desirable for the current paths 13, 14 to be narrow. On the other hand, when the width of the conductor 10 is increased for the width the through hole 15 to be increased, the two magnetic detection elements 21, 22 can be away from the current paths 13, 14, and the influence of the skin effect becomes relatively small, and thus it is possible to select a position at which the frequency characteristic is good. From the above description, in terms of the frequency characteristic, it is desirable to reduce the widths of the current paths 13, 14, or to increase the overall width of the conductor 10 such that the ratio of the widths of the current paths 13, 14 to the width of the conductor 10 is set to 20% or less.

FIG. 15 is a graph showing a relationship between a z coordinate of the one magnetic detection element 21 (or the magnetic detection element 22), and the magnetic flux density (mT) that is detected by the magnetic detection element 21. The horizontal axis of FIG. 15 represents the position on the magnetic sensing surface of the magnetic detection element 21 in the z direction, and is shown with the upper surface of the conductor 10 being set as the reference (z=0). The vertical axis of FIG. 15 represents the magnetic flux density (mT) that is detected by the magnetic detection element 21. FIG. 15 shows the maximum magnetic field when the current of ±1000 A and 2000 Hz is caused to flow. A simulation in which the magnetic detection element 21 was arranged 3.5 mm inward from the current path 13 in the x direction, and the thickness of the conductor 10 in the z direction was set to 2 mm, was performed.

As shown in FIG. 15, as the z coordinate of the magnetic detection element 21 is away from the upper surface of the conductor 10, the magnetic flux density that is detected, is decreased. When the magnetic flux density that is detected falls below 1 mT, a detection precision of the current measurement module 100 is not sufficient. Accordingly, it is desirable to arrange the magnetic detection element 21 such that the position of the magnetic sensing surface in the z direction is within 4 mm from the upper surface of the conductor 10. The same applies to the magnetic detection element 22. In addition, when the two magnetic detection elements 21, 22 are arranged on a −z direction side of the conductor 10, similarly, it is desirable to arrange them within 4 mm from a lower surface of the conductor 10.

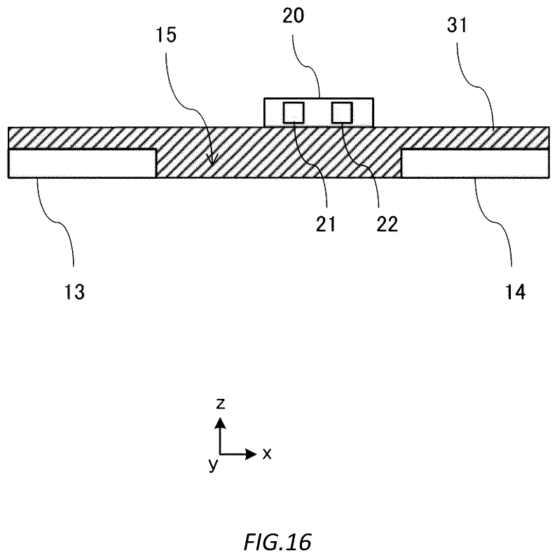

FIG. 16 shows a first example of a method for fixing a magnetic detection unit 20 to the conductor 10. As shown in FIG. 16, in the first example, the magnetic detection unit 20 is fixed to the conductor 10 via an insulation member 31 constituted by resin or the like. The insulation member 31 is arranged to cover the upper surface of the conductor 10 and fill the through hole 15. The magnetic detection unit 20 is fixed to an upper part of the insulation member 31.

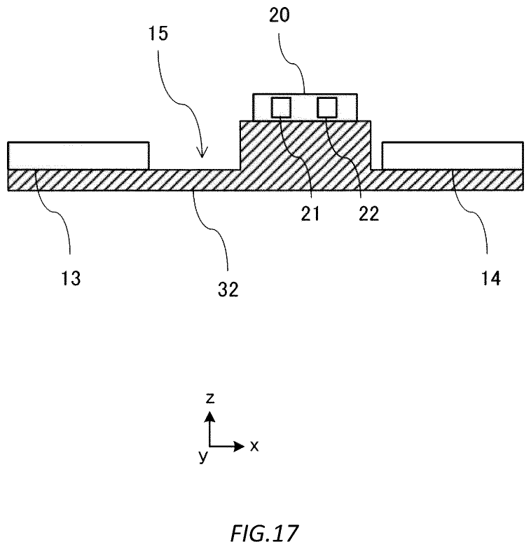

FIG. 17 shows a second example of the method for fixing the magnetic detection unit 20 to the conductor 10. As shown in FIG. 17, in the second example, the magnetic detection unit 20 is fixed to the conductor 10 via an insulation member 32 constituted by resin or the like. The insulation member 32 is arranged to cover the lower surface of the conductor 10 and fill a part of the through hole 15. The magnetic detection unit 20 is fixed to an upper part of the insulation member 32.

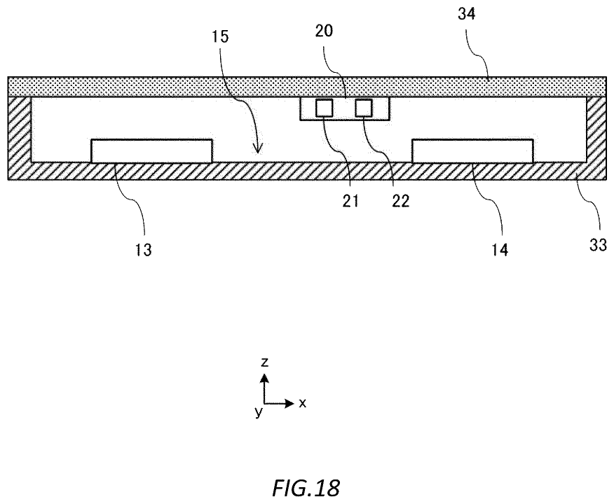

FIG. 18 shows a third example of the method for fixing the magnetic detection unit 20 to the conductor 10. As shown in FIG. 18, in the third example, the magnetic detection unit 20 is fixed to the conductor 10 via an insulation member 33 constituted by resin or the like and a substrate 34. The insulation member 33 is arranged to cover the lower surface and a side surface of the conductor 10. The substrate 34 connected to the insulation member 33 is arranged on an upper part of the conductor 10, and the magnetic detection unit 20 is fixed to a lower part of the substrate 34.

By fixing the magnetic detection unit 20 to the conductor 10 by using the methods in FIG. 16 to FIG. 18, it is possible to prevent the position of the magnetic detection unit 20 from being deviated in the z direction, and accordingly it is possible to enhance the measurement precision of the current measurement module 100. In addition, it is possible to set the current measurement module 100 to have a small size and a simple structure.

### (Effects of First Embodiment)

According to the current measurement module 100 in the first embodiment, the two magnetic detection elements 21, 22 are arranged at a position close to either one of the two current paths 13, 14 in the x direction. This makes it possible to ensure a sufficient magnetic flux density that is detected from the one current path which is set to be close, and makes it possible to enhance the S/N ratio of the current measurement module 100.

According to the current measurement module 100 in the first embodiment, the center distance between the two magnetic detection elements 21, 22 in the x direction is 2 mm or more. This makes it possible to increase the magnetic flux density that is detected by the differential output, and makes it possible to enhance the S/N ratio of the current measurement module 100.

According to the current measurement module 100 in the first embodiment, the width of each of the two current paths 13, 14 in the x direction is 20% or less of the width of the conductor 10 in the x direction. This makes it possible to enhance the frequency characteristic of the current measurement module 100.

According to the current measurement module 100 in the first embodiment, the two magnetic detection elements 21, 22 are arranged such that the positions of the magnetic sensing surfaces in the z direction are within 4 mm from the upper surface of the conductor 10. This makes it possible to increase the magnetic flux density that is detected from the two current paths 13, 14, and makes it possible to enhance the S/N ratio of the current measurement module 100. According to the current measurement module 100 in the first embodiment, both of the two magnetic detection elements 21, 22 are arranged to be 1 mm or more away from the inner end portions of the two current paths 13, 14 in the x direction. This makes it possible to enhance the frequency characteristic of the current measurement module 100.

### (Configuration of Second Embodiment)

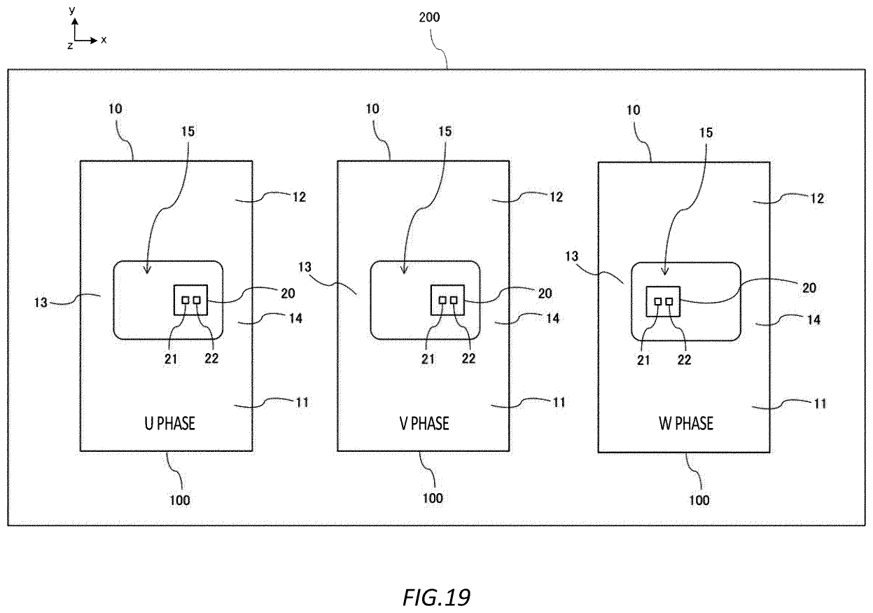

FIG. 19 is a top plan view showing an example of a schematic configuration of a current measurement device 200 in a second embodiment. In the following description of the second embodiment, parts common to the current measurement module 100 in the first embodiment are given the same signs and numerals and the descriptions thereof will be omitted. As shown in FIG. 19, the current measurement device 200 in the second embodiment includes three current measurement modules 100 in the first embodiment, and the three current measurement modules 100 are arranged side by side in the x direction.

A phase of the current flowing through the current measurement module 100 arranged on a left side, is delayed by 120° from a phase of the current flowing through the current measurement module 100 arranged in the center; and a phase of the current flowing through the current measurement module 100 arranged on a right side, is advanced by 120° from the phase of the current flowing through the current measurement module 100 arranged in the center. The three current measurement modules 100 correspond to a U phase, a V phase, and a W phase, respectively, in a three phase alternating current.

The center position of the two magnetic detection elements 21, 22 in the x direction, in the current measurement module 100 arranged on the left side, is arranged at a position close to the current path 14 on a side of the current measurement module 100 arranged in the center. The center position of the two magnetic detection elements 21, 22 in the x direction, in the current measurement module 100 arranged in the center, is arranged at a position close to the current path 14 on a side of the current measurement module 100 arranged on the right side. The center position of the two magnetic detection elements 21, 22 in the x direction, in the current measurement module 100 arranged on the right side, is arranged at a position close to the current path 13 on a side of the current measurement module 100 arranged in the center.

### (Configuration of Third Embodiment)

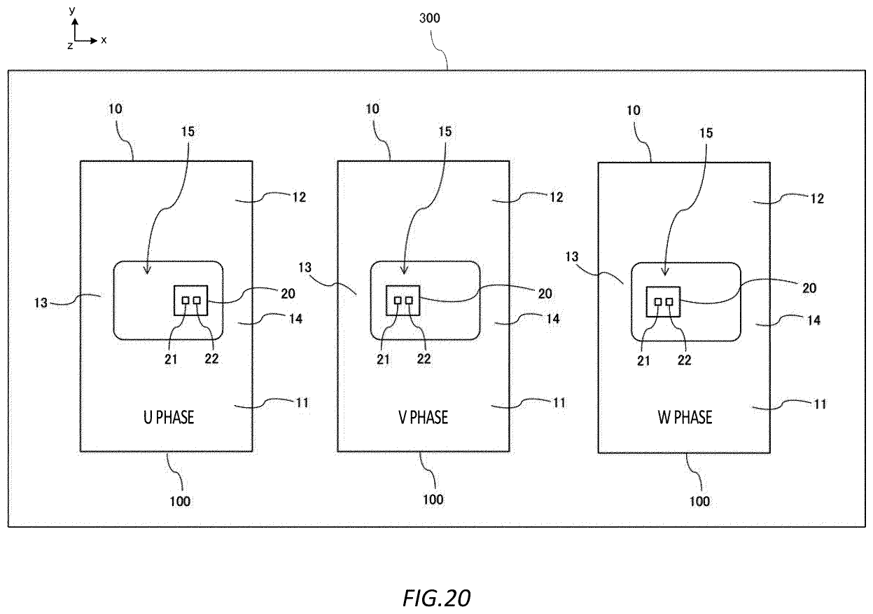

FIG. 20 is a top plan view showing an example of a schematic configuration of a current measurement device 300 in a third embodiment. In the following description of the third embodiment, parts common to the current measurement module 100 in the first embodiment are given the same signs and numerals and the descriptions thereof will be omitted. As shown in FIG. 20, the current measurement device 300 in the third embodiment includes three current measurement modules 100 in the first embodiment, and the three current measurement modules 100 are arranged side by side in the x direction.

The phase of the current flowing through the current measurement module 100 arranged on the left side, is advanced by 120° from the phase of the current flowing through the current measurement module 100 arranged in the center; and the phase of the current flowing through the current measurement module 100 arranged on the right side, is delayed by 120° from the phase of the current flowing through the current measurement module 100 arranged in the center. The three current measurement modules 100 correspond to a U phase, a V phase, and a W phase, respectively, in a three phase alternating current.

The center position of the two magnetic detection elements 21, 22 in the x direction, in the current measurement module 100 arranged on the left side, is arranged at a position close to the current path 14 on a side of the current measurement module 100 arranged in the center. The center position of the two magnetic detection elements 21, 22 in the x direction, in the current measurement module 100 arranged in the center, is arranged at a position close to the current path 13 on a side of the current measurement module 100 arranged on the left side. The center position of the two magnetic detection elements 21, 22 in the x direction, in the current measurement module 100 arranged on the right side, is arranged at a position close to the current path 13 on a side of the current measurement module 100 arranged in the center.

### (Configuration of Comparative Example)

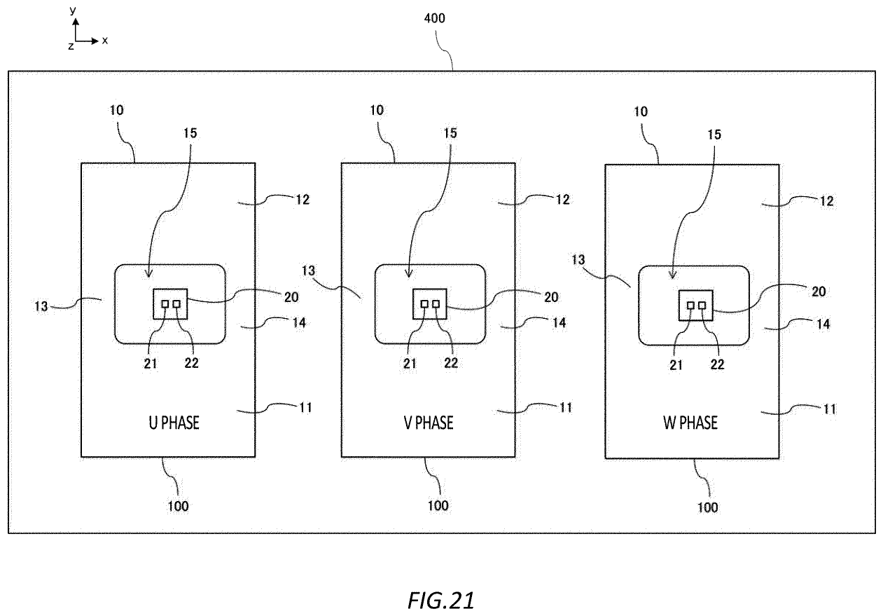

FIG. 21 is a top plan view showing an example of a schematic configuration of a current measurement device 400 in a comparative example. In the following description of the comparative example, parts common to the current measurement module 100 in the first embodiment are given the same signs and numerals and the descriptions thereof will be omitted. As shown in FIG. 21, the current measurement device 400 in the comparative example includes three current measurement modules 100 in the first embodiment, and the three current measurement modules 100 are arranged side by side in the x direction.

The phase of the current flowing through the current measurement module 100 arranged on the left side, is advanced by 120° from the phase of the current flowing through the current measurement module 100 arranged in the center; and the phase of the current flowing through the current measurement module 100 arranged on the right side, is delayed by 120° from the phase of the current flowing through the current measurement module 100 arranged in the center. The three current measurement modules 100 correspond to a U phase, a V phase, and a W phase, respectively, in a three phase alternating current.

The two magnetic detection elements 21, 22 in the three current measurement modules 100 are arranged such that the center position of the two magnetic detection elements in the x direction 21, 22 coincides with the center of the through hole 15. That is, in the comparative example, the two magnetic detection elements 21, 22 are not arranged to be close to either of the current paths 13, 14.

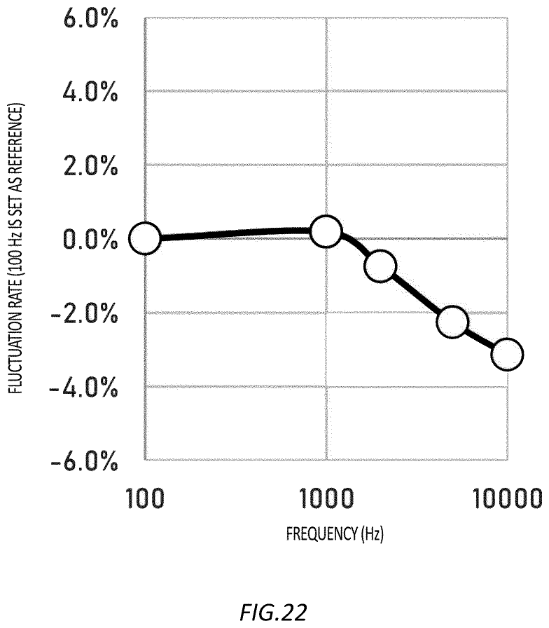

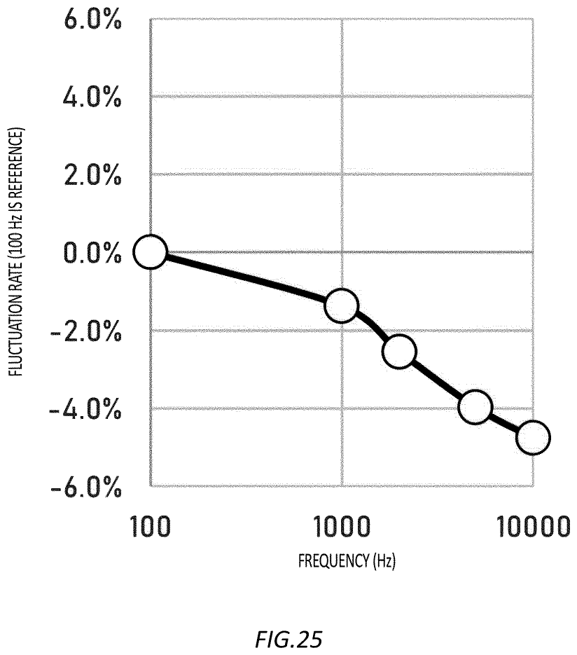

FIG. 22 to FIG. 27 are graphs showing a comparison of the frequency characteristic between the current measurement device 200 in the second embodiment and the current measurement device 400 in the comparative example. FIG. 22 to FIG. 24 respectively show the frequency characteristics of the current measurement modules 100 of the U phase, the V phase, and the W phase in the current measurement device 200 in the second embodiment; and FIG. 25 to FIG. 27 respectively show the frequency characteristics of the current measurement modules 100 of the U phase, the V phase, and the W phase in the current measurement device 400 in the comparative example. In FIG. 22 to FIG. 27, the horizontal axis represents the frequency (Hz) of the current flowing through the current measurement module 100, and the vertical axis represents the fluctuation rate (%) of the magnetic flux density when 100 Hz is set as the reference.

As shown in FIG. 22, in the current measurement module 100 of the U phase in the current measurement device 200, the magnetic flux density hardly fluctuates at 1000 Hz, and settles down to a decrease of approximately −3% at 10000 Hz. In contrast with this, as shown in FIG. 25, in the current measurement module 100 of the U phase in the current measurement device 400, the magnetic flux density is decreased to around −1.5% at 1000 Hz, and is decreased to around −5% at 10000 Hz. Accordingly, it can be seen that for the current measurement module 100 of the U phase, the frequency characteristic is better in the current measurement device 200 in the second embodiment than in the current measurement device 400 in the comparative example.

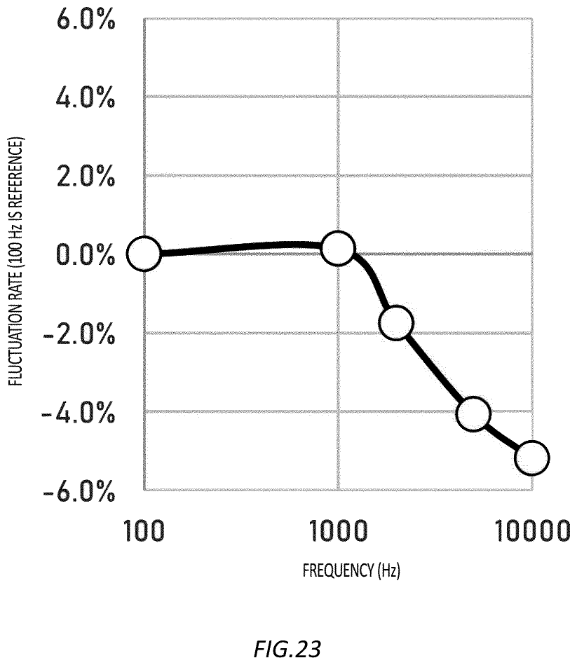

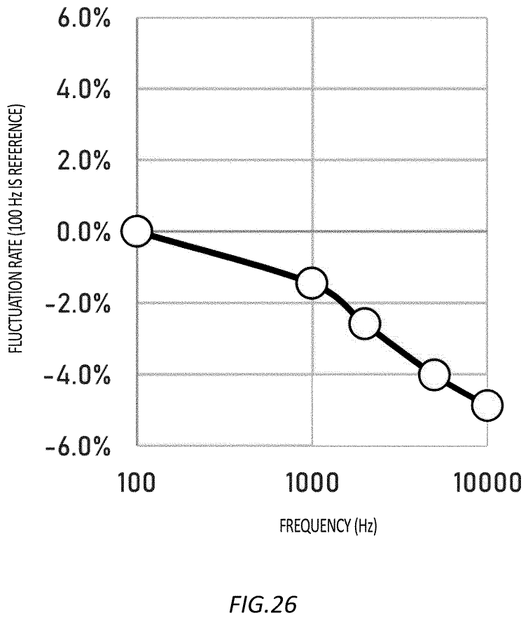

As shown in FIG. 23, in the current measurement module 100 of the V phase in the current measurement device 200, the magnetic flux density hardly fluctuates at 1000 Hz, and settles down to a decrease of approximately −5% at 10000 Hz. In contrast with this, as shown in FIG. 26, in the current measurement module 100 of the V phase in the current measurement device 400, the magnetic flux density is decreased to around −1.5% at 1000 Hz, and is decreased to around −5% at 10000 Hz. Accordingly, it can be seen that for the current measurement module 100 of the V phase, the frequency characteristic is better in the current measurement device 200 in the second embodiment than in the current measurement device 400 in the comparative example.

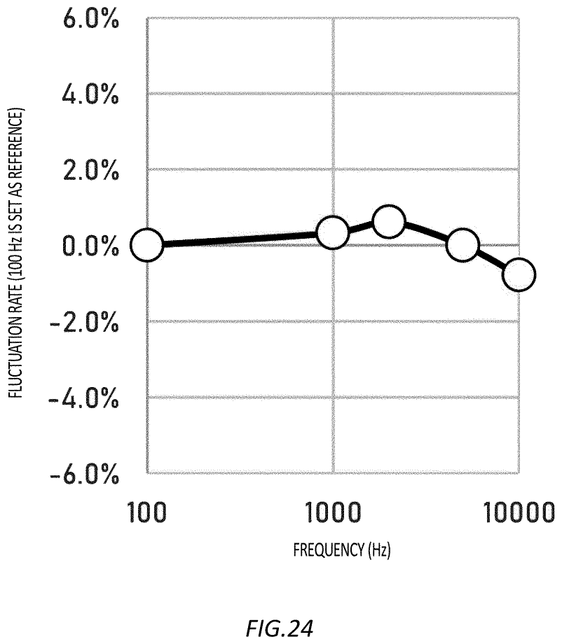

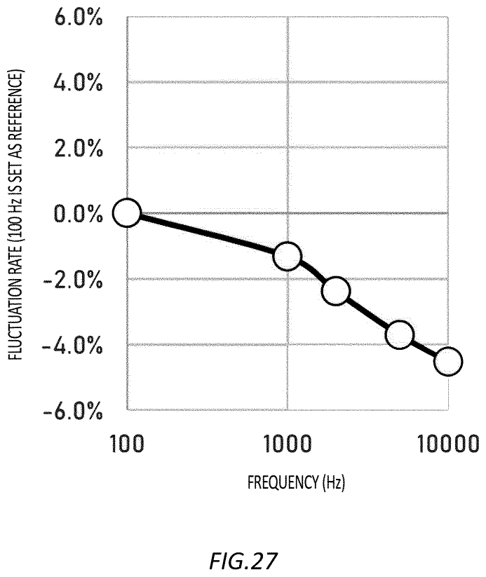

As shown in FIG. 24, in the current measurement module 100 of the W phase in the current measurement device 200, the magnetic flux density hardly fluctuates at 1000 Hz, and settles down to a decrease of approximately −1% at 10000 Hz. In contrast with this, as shown in FIG. 27, in the current measurement module 100 of the W phase in the current measurement device 400, the magnetic flux density is decreased to around −1.5% at 1000 Hz, and is decreased to around −4.5% at 10000 Hz. Accordingly, it can be seen that for the current measurement module 100 of the W phase, the frequency characteristic is better in the current measurement device 200 in the second embodiment than in the current measurement device 400 in the comparative example.

From the above description, it can be seen that for any of the U phase, the V phase, or the W phase, the frequency characteristic is better in the current measurement device 200 in the second embodiment than in the current measurement device 400 in the comparative example, and accordingly the arrangement configuration of the current measurement device 200 in the second embodiment is desirable. It should be noted that similar to the current measurement device 200 in the second embodiment, the current measurement device 300 in the third embodiment also has a better frequency characteristic than the current measurement device 400 in the comparative example.

### (Advantages of Second and Third Embodiments)

According to the current measurement device 200 in the second embodiment and the current measurement device 300 in the third embodiment, the three current measurement modules 100 are arranged side by side in the x direction, and the two magnetic detection elements 21, 22 in the three current measurement modules 100 are arranged at a position close to either of the current paths 13, 14. This makes it possible to enhance the frequency characteristics of the current measurement device 200 and the current measurement device 300.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: conductor;
11, 12: main body unit;
13, 14: current path;
15: through hole;
20: magnetic detection unit;
21, 22: magnetic detection element;
31 to 33: insulation member;
34: substrate;
100: current measurement module;
200, 300, 400: current measurement device.

What is claimed is:

1. A current measurement module comprising:
a conductor which has two main body units arranged side by side in a first direction, and two current paths arranged side by side across a through hole in a second direction perpendicular to the first direction, and connecting the two main body units; and
two magnetic detection elements which include magnetic sensing surfaces for detecting a component in a third direction perpendicular to the first direction and the second direction, in magnetic fields that are generated by currents flowing through the two current paths, and which are arranged side by side in the second direction, wherein
when viewed from the third direction, the two magnetic detection elements are arranged inside the through hole, and
in the second direction, a center position between the two magnetic detection elements is close to either one of the two current paths.

2. The current measurement module according to claim 1, wherein a center distance between the two magnetic detection elements in the second direction is 2 mm or more.

3. The current measurement module according to claim 1, wherein
a distance between the two magnetic detection elements in the second direction is 15% or more of a width of the through hole in the second direction.

4. The current measurement module according to claim 1, wherein a width of each of the two current paths in the second direction is 20% or less of a width of the conductor in the second direction.

5. The current measurement module according to claim 1, wherein a width of each of the two current paths in the second direction is 4 mm or less.

6. The current measurement module according to claim 1, wherein widths of the two current paths in the second direction are the same as each other.

7. The current measurement module according to claim 1, wherein positions of the magnetic sensing surfaces of the two magnetic detection elements in the third direction are in a range of 4 mm from upper surfaces of the two current paths.

8. The current measurement module according to claim 1, wherein a width of the conductor in the third direction is 4 mm or less.

9. The current measurement module according to claim 1, wherein
a current path which is close to the center position between the two magnetic detection elements, in the second direction, is set as a first current path, and
both of the two magnetic detection elements are arranged 1 mm or more away from an inner end portion of the first current path.

10. The current measurement module according to claim 1, wherein
a current path which is close to the center position between the two magnetic detection elements, in the second direction, is set as a first current path, and
a center distance between the two magnetic detection elements is greater than a distance between a center position of a magnetic detection element, among the two magnetic detection elements, on a side of the first current path, and an end portion of the first current path.

11. The current measurement module according to claim 1, wherein the two magnetic detection elements are arranged to face each other with respect to a center of the through hole, in the second direction.

12. The current measurement module according to claim 1, wherein the two magnetic detection elements are arranged to face each other, in the second direction, across a region in which magnetic fields that are generated by currents flowing through the two current paths cancel out each other when a current flows through the conductor and a magnetic flux density in the third direction that is detected becomes zero.

13. The current measurement module according to claim 1, wherein the two magnetic detection elements are Hall elements.

14. The current measurement module according to claim 1, further comprising an insulation member for fixing the two magnetic detection elements to the conductor.

15. The current measurement module according to claim 1, further comprising a substrate for fixing the two magnetic detection elements to the conductor.

16. A current measurement device comprising:
three current measurement modules, each of which is the current measurement module according to claim 1, and which are arranged side by side in the second direction,
wherein in the second direction,
a center position of the two magnetic detection elements in the current measurement module arranged on a left side is arranged at a position close to a current path on a side of the current measurement module arranged in a center,
a center position of the two magnetic detection elements in the current measurement module arranged in the center is arranged at a position close to a current path on a side of the current measurement module arranged on a right side, and
a center position of the two magnetic detection elements in the current measurement module arranged on the right side is arranged at a position close to a current path on a side of the current measurement module arranged in the center.

17. The current measurement device according to claim 16, wherein
a phase of a current flowing through the current measurement module arranged on the left side is delayed by 120° from a phase of a current flowing through the current measurement module arranged in the center; and a phase of a current flowing through the current measurement module arranged on the right side is advanced by 120° from a phase of a current flowing through the current measurement module arranged in the center.

18. A current measurement device comprising:
three current measurement modules, each of which is the current measurement module according to claim 1, and which are arranged side by side in the second direction,
wherein in the second direction,
a center position of the two magnetic detection elements in the current measurement module arranged on a left side is arranged at a position close to a current path on a side of the current measurement module arranged in a center,
a center position of the two magnetic detection elements in the current measurement module arranged in the center is arranged at a position close to a current path on a side of the current measurement module arranged on the left side, and
a center position of the two magnetic detection elements in the current measurement module arranged on a right side is arranged at a position close to a current path on a side of the current measurement module arranged in the center.

19. The current measurement device according to claim 18, wherein
a phase of a current flowing through the current measurement module arranged on the left side is advanced by 120° from a phase of a current flowing through the current measurement module arranged in the center; and a phase of a current flowing through the current measurement module arranged on the right side is delayed by 120° from a phase of a current flowing through the current measurement module arranged in the center.
